(19) United States
(12) Patent Application Publication
(10) Pub. No.: US 2016/0013396 A1
(43) Pub. Date: Jan. 14, 2016

(54) VIBRATION DETECTING APPARATUS AND MOBILE DEVICE INCLUDING THE SAME

(71) Applicant: SAMSUNG ELECTRO-MECHANICS CO., LTD., Suwon-si (KR)

(72) Inventors: Il-Kwon CHUNG, Suwon (KR); Byeong-Sung MIN, Suwon (KR); Hyun-Ho LIM, Suwon (KR)

(73) Assignee: SAMSUNG ELECTRO-MECHANICS CO., LTD., Suwon-si (KR)

(21) Appl. No.: 14/664,097

(22) Filed: Mar. 20, 2015

(30) Foreign Application Priority Data
Jul. 14, 2014 (KR) 10-2014-0088508

(51) Int. Cl. H01L 41/113; G06F 3/01

(52) U.S. Cl. CPC H01L 41/1136; H01L 41/1132; G06F 3/016

(57) ABSTRACT

Vibration detecting apparatus and mobile device including the same disclosed. A vibration detecting apparatus includes a base, a piezoelectric body having one end thereof supported by the base and the other end thereof freed and configured for converting a mechanical stress being applied by a vibration of the base into an electrical signal, an electrode coupled to the piezoelectric body so as to transmit the electrical signal to a measuring circuit and an elastic body coupled to the piezoelectric body so as to elastically press the piezoelectric body in an opposite direction to the mechanical stress being applied to the piezoelectric body.

### CROSS-REFERENCE TO RELATED APPLICATIONS

This application claims the benefit of Korean Patent Application No. 10-2014-0088508, filed with the Korean Intellectual Property Office on Jul. 14, 2014, the disclosure of which is incorporated herein by reference in its entirety.

### BACKGROUND

1. Technical Field

The present invention relates to a vibration detecting apparatus and a mobile device including the same.

2. Background Art

Various mobile devices such as a cellular phone that are carried and used by a user have been developed to integrate various functions in one mobile device. For example, there have been active studies for developing the mobile devices to be implemented as a multimedia player having combined functions including taking pictures or video, playing music or video files, playing games, receiving broadcast signals and so on.

In addition, in order to support and enhance these functions of mobile devices, it is possible to consider improving the structures and/or software of the mobile devices.

As one example, new designs for mobile devices adopting the touch screen functionality have been introduced in the market. In these new touch screen mobile devices, the user may be required to input a password or a specific pattern repeatedly in order to use some functions of the mobile devices, causing an inconvenience of use.

Thus, it is needed to study for a new user interface (UI) that allows the user to operate various functions of the mobile device more conveniently.

### SUMMARY

An embodiment of the present invention relates to a vibration detecting apparatus configured for detecting a vibration by converting a mechanical stress caused by the vibration to an electric signal, and a mobile device including the same.

The vibration detecting apparatus may detect a pattern of the vibration by use of a plurality of piezoelectric bodies having different lengths and may control the operation of a display module provided in the mobile device based on the detected vibration pattern.

### BRIEF DESCRIPTION OF DRAWINGS

FIG. 1 shows an exemplary embodiment of a vibration detecting apparatus.

FIG. 2 illustrates an operation state of the vibration detecting apparatus. FIG. 3 shows another exemplary embodiment of a vibration detecting apparatus.

FIG. 4 shows an exemplary configuration of a mobile device having the vibration detecting apparatus.

FIG. 5 shows an example of the mobile device.

FIG. 6 shows examples of vibration patterns that may be detected in the mobile device.

### DETAILED DESCRIPTION

Hereinafter, a vibration detecting apparatus and a mobile device including the same in accordance with the present invention will be described with reference to the accompanying drawings. In describing the present invention with reference to the accompanying drawings, any identical or corresponding elements will be assigned with same reference numerals, and their description will not be provided redundantly.

When one element is described to be “coupled” to another element, it does not refer to a physical, direct electrode between these elements only, but it shall also include the possibility of yet another element being interposed between these elements and each of these elements being in electrode with said yet another element.

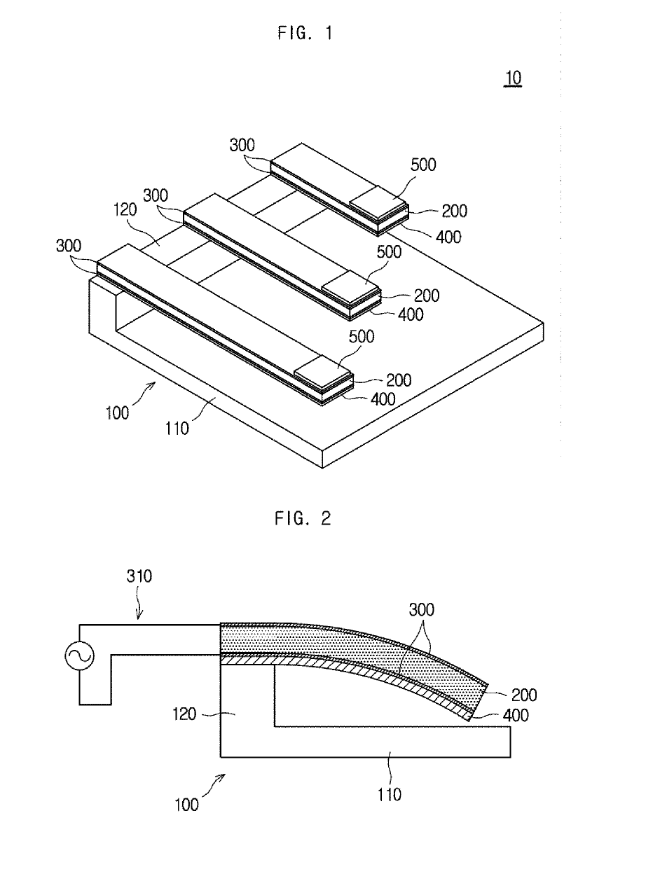

FIG. 1 shows an exemplary embodiment of a vibration detecting apparatus, and FIG. 2 illustrates an operation state of the vibration detecting apparatus.

As shown in FIG. 1 and FIG. 2, a vibration detecting apparatus 10 according to the exemplary embodiment includes a base 100, a piezoelectric body 200, an electrode 300, and an elastic body 400, and may further include a weight 500.

The base 100 supports one end of the piezoelectric body 200, and a vibration applied to the base 100 from an outside may be transferred to the piezoelectric body 200. In such a case, the base 100 may be made of a material with a rigidity sufficient to securely support the piezoelectric body 200.

Although FIG. 1 and FIG. 2 show an example of the shape of the base 100, the shape of the base 100 shall not be limited to what is illustrated herein but may be varied to any shapes as long as the piezoelectric body 200 may be supported and the vibration may be transferred to the piezoelectric body 200.

The piezoelectric body 200 has one end thereof supported by the base 100 and the other end thereof freed and is configured for converting a mechanical stress applied by the vibration of the base 100 to an electrical signal. The piezoelectric body 200 may be made of a piezoelectric material, for example, piezoelectric ceramics.

When a pressure is applied to a piezoelectric material, an output voltage is changed (piezoelectric effect), and when a voltage is applied, the piezoelectric material is expanded or contracted. This means that the piezoelectric material is capable of converting the mechanical stress into the electrical signal.

Specifically, the vibration that is applied to the base 100 from the outside may be delivered to the piezoelectric body 200 to allow the other end of the piezoelectric body 200 to move freely, during which the mechanical stress is applied to the piezoelectric body 200 to change the voltage in the piezoelectric body 200 due to the piezoelectric effect.

Here, the changed voltage being outputted from the piezoelectric body 200 is referred to as the electrical signal.

The electrodes 300, which are coupled to the piezoelectric body 200 to deliver the electrical signal from the piezoelectric body 200 to a measuring circuit 310, are coupled to at least two points in the piezoelectric body 200 to work as a cathode and an anode. The electrodes 300 that work as the cathode and the anode are coupled to the measuring circuit 310 to measure the electrical signal, for example, the voltage that the piezoelectric body 200 generates.

Here, as illustrated in FIG. 1 and FIG. 2, the electrodes 300 may be formed on, but not limited to, a top surface and a bottom surface of the piezoelectric body 200, but may be formed on any of lateral surfaces of the piezoelectric body 200 if necessary.

The electrical signal measured by the measuring circuit 310 may vary according to the properties of vibration (for example, vibrations having different frequencies, intensities, or durations) that are given from the outside. Thus, by analyzing the electrical signal, it is possible to assess the properties of vibration.

The elastic body 400 is coupled to the piezoelectric body 200 to elastically press the piezoelectric body 200 in an opposite direction to the mechanical stress being applied to the piezoelectric body 200. Accordingly, the piezoelectric body 200 is allowed to vibrate continuously when the vibration is delivered to the piezoelectric body 200.

Here, the elasticity is the nature of an object that tends to restitute to its original shape when an external force that has deformed the object is removed.

Considering that the piezoelectric materials such as the piezoelectric ceramics are non-elastic materials, an intermittent movement may occur, but it may not be possible to vibrate continuously, when the vibration is applied from the outside.

Thus, by coupling the elastic body 400 to the piezoelectric body 200, the piezoelectric body 200 may vibrate continuously when the vibration is applied from the outside.

As such, by allowing the vibration detecting apparatus 10 according to the exemplary embodiment to convert the mechanical stress being caused by the vibration into the electrical signal to detect the vibration, it becomes possible to identify the properties of vibrations that are applied from the outside.

In addition, unlike the conventional inertial sensor that is often used to measure the vibration but has a relatively large power consumption, it may become possible to measure the vibration with a relatively low power consumption.

The vibration detecting apparatus 10 according to the exemplary embodiment may have a plurality of piezoelectric bodies 200 that are protruded from the base 100 and have different lengths. The electrodes 300 and the elastic bodies 400 may be coupled to each of the plurality of piezoelectric bodies 200.

That is, as shown in FIG. 1, considering that the plurality of piezoelectric bodies 200 have different vibration frequencies due to the different lengths of the portions that can vibrate, the plurality of piezoelectric bodies 200 may each vibrate in a different pattern for the vibration that is applied from the outside.

Thus, by analyzing the combination of vibration patterns of each of the plurality of piezoelectric bodies 200, it becomes possible to determine the properties of the vibration (e.g., frequency, intensity, duration, etc.) in various perspectives.

The weights 500 are coupled, respectively, to the other ends of the piezoelectric bodies 200 so as to press the piezoelectric bodies 200, and may amplify the vibration of the piezoelectric bodies 200. That is, when a weak vibration is applied from the outside, the vibration of the piezoelectric body 200 is initiated meagerly. However, the vibration may be amplified by allowing the weight 500 to press the piezoelectric body 200 in one direction and the elastic body 400 to press the piezoelectric body 200 in an opposite direction despite the meager initial vibration.

Thus, the vibration detecting apparatus 10 according to the exemplary embodiment may respond sensitively to the relatively weak vibration so that it becomes possible to detect the vibration more precisely.

In the vibration detecting apparatus 10 according to the exemplary embodiment, the elastic body 400 may be formed by coating a polymer resin on an external surface of the piezoelectric body 200. That is, the polymer resin, which has elasticity, may be coated on the external surface of the piezoelectric body 200 instead of coupling any elastic body to the piezoelectric body 200.

In this case, the polymer resin may be made of a polymeric compound that has good elasticity and mechanical properties such as flexural strength, hardness, etc.

Under a condition in which the piezoelectric body 200 and the electrode 300 are coupled to each other, any of the surfaces of the piezoelectric body 200 and the electrode 300 that is exposed to the outside may be coated with the polymer resin.

Accordingly, the durability may be improved by minimizing the piezoelectric body 200 and the electrode 300 from being exposed to the outside while the elastic body 400 performs the basic function of vibrating the piezoelectric body 200 continuously.

FIG. 3 shows another exemplary embodiment of a vibration detecting apparatus.

As shown in FIG. 3, in a vibration detecting apparatus 11 according to another exemplary embodiment, a plurality of piezoelectric bodies 200 have different widths in portions that are projected from a base 100. Electrodes 300 and elastic bodies 400 may be each coupled to each of the plurality of the piezoelectric bodies 200.

That is, as shown in FIG. 3, considering that the plurality of piezoelectric bodies 200 have different vibration frequencies due to the different widths of portions that can vibrate, the plurality of piezoelectric bodies 200 may each vibrate in a different pattern for vibrations that are applied from an outside.

Thus, by analyzing a combined pattern of vibrations of each of the piezoelectric bodies 200, it becomes possible to assess the properties of vibrations (e.g., frequency, intensity, duration, etc.) in various perspectives.

Except for the above-described elements, most elements of the vibration detecting apparatus 10 according to another exemplary embodiment are identical or similar to those of the vibration detecting apparatus 11 according to one exemplary embodiment, and thus any redundant description will not be provided herein.

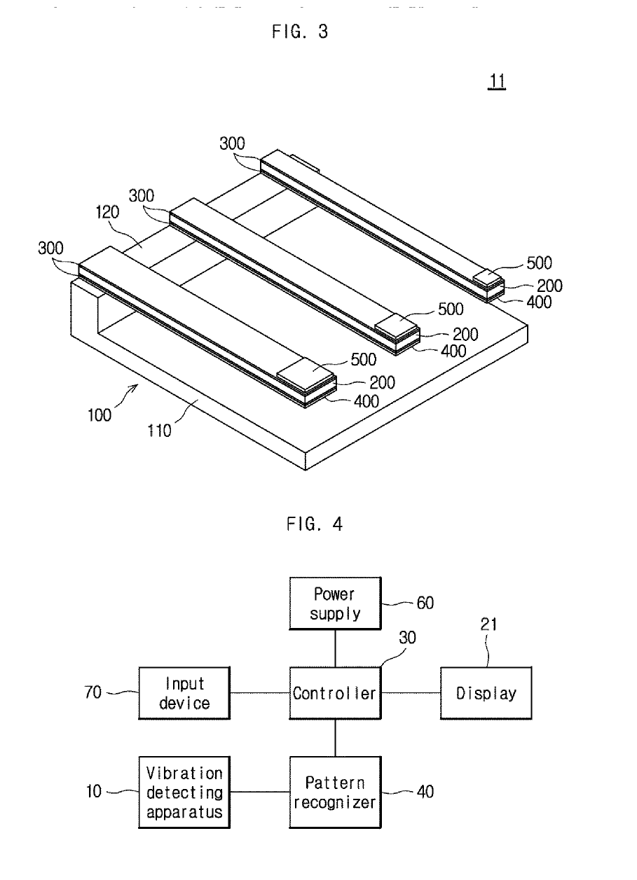

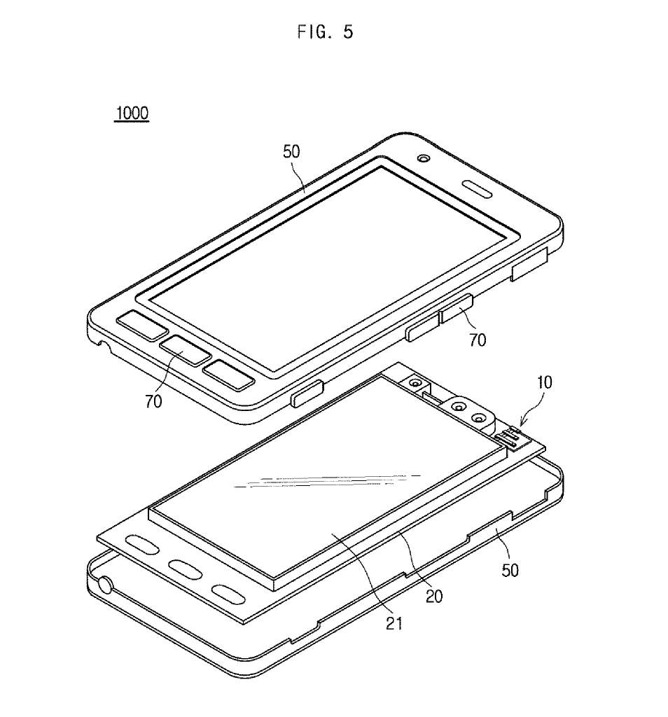

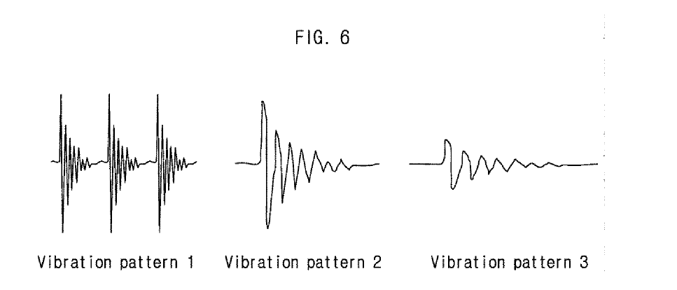

FIG. 4 shows an exemplary configuration of a mobile device having the vibration detecting apparatus, FIG. 5 shows an example of the mobile device, and FIG. 6 shows examples of vibration patterns that may be detected in the mobile device.

As shown in FIG. 4 to FIG. 6, a mobile device 1000 according to one exemplary embodiment includes the vibration detecting apparatus 10, a main body 20, and a controller 30, and may further include a pattern sensor 40.

Moreover, the mobile device 1000 may include a power supply 60 for providing power, an input device 70, such as a keypad, a switch, and a jog-wheel, for the user to generate input data for controlling the operation of the mobile device 1000, and a case 50 for covering the main components.

The mobile device 1000 refers to any of various portable electronic devices, such as a mobile phone, a smart phone, a laptop computer, a digital broadcasting terminal, a PDA (Personal Digital Assistant), a PMP (Portable Multimedia Player), a GPS navigation device, and so on. For the purpose of providing an illustrative description, FIG. 5 illustrates a mobile phone as the mobile device 1000, but it shall be appreciated that the mobile device 1000 is not limited to the mobile phone.

The vibration detecting apparatus 10 converts a mechanical stress caused by a vibration into an electrical signal for detection of the vibration and is capable of identifying the properties of the vibration that is applied from an outside. Since the vibration detecting apparatus 10 has been described above in detail, it will not be redundantly described herein.

The main body 20 is provided with a display module 21 and has the vibration detecting apparatus 10 installed therein, and may further include a main board, an AP (Application Processor) and various circuits.

Here, the display module 21 is configured for displaying information processed by the mobile device 1000, and may be implemented with various functions, for example, displaying a clock or a call status, operating a camera, and so on, according to an operation command inputted by a user.

The display module 21 may be one of, but not limited to, an LCD (liquid crystal display), a TFT-LCD (thin film transistor-liquid crystal display), an OLED (organic light-emitting diode), a flexible display, and a 3D display.

In addition, the display module 21 may further include a touch screen configured for allowing the operation commend to be inputted by a touch of the user.

The controller 30 is configured for controlling the operation of the display module 21 based on the electrical signal generated by the vibration detecting apparatus 10, and may allow the display module 21 to be operated based on the properties of vibration that is applied from the outside.

For example, in case it is determined that the vibration is not intended by the user based on an analysis of the electric signal because the vibration is irregular, the display module 21 may be controlled not to operate.

In contrast, in case it is determined that the vibration is intended by the user based on the analysis of the electric signal because the vibration is regular, the display module 21 may be controlled to operate.

As such, the mobile device 1000 of the exemplary embodiment may control the display module 21 to operate according to the properties of the vibration that is applied from the outside, thereby further improving the user convenience.

The pattern sensor 40 is configured for detecting the vibration pattern by receiving the electrical signal generated by the vibration detecting apparatus 10 and may match the properties of the vibration with a most similar vibration pattern among various pre-stored vibration patterns.

For example, vibration patterns 1 to 3 shown in FIG. 6 may be pre-stored in the pattern sensor 40, and then the most similar vibration pattern among the vibration patterns 1 to 3 may be matched with the vibration pattern of a piezoelectric body 200. If two or more piezoelectric bodies 200 are used, vibration patterns of the piezoelectric bodies 200 may be combined and matched against the pre-stored vibration patterns.

Here, the controller 30 may control the display module 21 to execute a predetermined operation based on the type of the detected vibration pattern. As described above, the predetermined operation may be, for example, displaying a clock or a call status, operating a camera and so on.

In case different vibrations are applied intentionally to the mobile device 1000 by the user, an execution command for the operation corresponding to each different vibration applied by the user may be identified through the pattern sensor 40.

Moreover, by allowing the display module 21 to operate automatically according to the identified execution command, the user may input various operation commands just by applying various vibrations without using the input device 70.

In the mobile device 1000 according to the exemplary embodiment, the base 100 may include a base plate 110 and a support 120.

The base plate 110 has one plate-shape surface attached to the main body 20 to receive the vibration applied to the mobile device 1000 from the outside through a larger area.

The support 120 is projected from the other plate-shape surface of the base plate 110 to support the piezoelectric body 200 and may separate the piezoelectric body 200 from the base plate 100 so as to allow the other end of the piezoelectric body 200 to vibrate freely.

Although it is illustrated in FIG. 4 and FIG. 5 that the mobile device 1000 includes the vibration detecting apparatus 10 according to one exemplary embodiment, it shall be appreciated that the mobile device 1000 may include the vibration detecting apparatus 11 according to another exemplary embodiment.

Although certain embodiments of the present invention have been described above, it shall be appreciated that there can be a variety of permutations and modifications of the present invention by those who are ordinarily skilled in the art to which the present invention pertains without departing from the technical ideas and scope of the present invention, which shall be defined by the appended claims. It shall be also appreciated that a large number of other embodiments than the above-described embodiments are included in the claims of the present invention.

What is claimed is:

1. A vibration detecting apparatus, comprising:
a base;
a piezoelectric body having one end thereof supported by the base and the other end thereof freed and configured for converting a mechanical stress being applied by a vibration of the base into an electrical signal;
an electrode coupled to the piezoelectric body so as to transmit the electrical signal to a measuring circuit; and
an elastic body coupled to the piezoelectric body so as to elastically press the piezoelectric body in an opposite direction to the mechanical stress being applied to the piezoelectric body.

2. The vibration detecting apparatus of claim 1, wherein the piezoelectric body is provided in plurality, each of the plurality of piezoelectric bodies having a different length, and
wherein the electrode and the elastic body are each coupled to each of the plurality of piezoelectric bodies.

3. The vibration detecting apparatus of claim 1, wherein the piezoelectric body is provided in plurality, each of the plurality of piezoelectric bodies having a portion thereof protruded with a different width from the base, and
wherein the electrode and the elastic body are each coupled to each of the plurality of piezoelectric bodies.

4. The vibration detecting apparatus of claim 1, further comprising a weight coupled to the other end of the piezoelectric body so as to press the piezoelectric body with a self-load.

5. The vibration detecting apparatus of claim 1, wherein the elastic body is formed by coating a polymer resin on an external surface of the piezoelectric body.

6. A mobile device, comprising:
a vibration detecting apparatus comprising:
a base;
a piezoelectric body having one end thereof supported by the base and the other end thereof freed and configured for converting a mechanical stress being applied by a vibration of the base into an electrical signal;
an electrode coupled to the piezoelectric body so as to transmit the electrical signal to a measuring circuit; and
an elastic body coupled to the piezoelectric body so as to elastically press the piezoelectric body in an opposite direction to the mechanical stress being applied to the piezoelectric body,
a main body having a display module therein and having the vibration detecting apparatus installed therein; and
a controller configured for controlling an operation of the display module according to the electric signal generated by the vibration detecting apparatus.

7. The mobile device of claim 6, further comprising a pattern sensor configured for detecting a vibration pattern by receiving the electric signal generated by the vibration detecting apparatus,
wherein the controller is configured to control the display module to execute a predetermined operation based on the vibration pattern.

8. The mobile device of claim 6, wherein the base comprises:
a base plate having one plate-shape surface thereof attached to the main body; and
a support projected on the other surface of the base plate and configured for supporting the piezoelectric body.
